(19) United States
(12) Patent Application Publication
(10) Pub. No.: US 2014/0084399 A1
(43) Pub. Date: Mar. 27, 2014

(54) SPIN TRANSFER TORQUE MEMORY (STTM) DEVICE WITH TOPOGRAPHICALLY SMOOTH ELECTRODE AND METHOD TO FORM SAME

(71) Applicants: Mark L. Doczy, Portland, OR (US); Kaan Oguz, Dublin (IE); Brian S. Doyle, Portland, OR (US); Robert S. Chau, Beaverton, OR (US)

(72) Inventors: Mark L. Doczy, Portland, OR (US); Kaan Oguz, Dublin (IE); Brian S. Doyle, Portland, OR (US); Robert S. Chau, Beaverton, OR (US)

(21) Appl. No.: 13/629,162

(22) Filed: Sep. 27, 2012

(51) Int. Cl. H01L 29/82; H01L 21/02

(52) U.S. Cl. 257/421; 438/3; 257/E29.323; 257/E21.002

(57) ABSTRACT

Spin transfer torque memory (STTM) devices with topographically smooth electrodes and methods of fabricating STTM devices with topographically smooth electrodes are described. For example, a material layer stack for a magnetic tunneling junction includes a topographically smooth bottom electrode, a topographically smooth dielectric layer disposed above the bottom electrode, and a free magnetic layer disposed above the topographically smooth dielectric layer.

### TECHNICAL FIELD

Embodiments of the invention are in the field of memory devices and, in particular, spin transfer torque memory (STTM) devices with topographically smooth electrodes and methods of fabricating STTM devices with topographically smooth electrodes.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased capacity. The drive for ever-more capacity, however, is not without issue. The necessity to optimize the performance of each device becomes increasingly significant.

The operation of spin torque devices is based on the phenomenon of spin transfer torque. If a current is passed through a magnetization layer, called the fixed magnetic layer, it will come out spin polarized. With the passing of each electron, its spin (which is angular momentum of the electron) will be added to the magnetization in a next magnetic layer, called the free magnetic layer, and will cause its small change. This is, in effect, a torque-causing precession of magnetization. Due to reflection of electrons, a torque is also exerted on the magnetization of an associated fixed magnetic layer. In the end, if the current exceeds a certain critical value (given by damping caused by the magnetic material and its environment), the magnetization of the free magnetic layer will be switched by a pulse of current, typically in about 1 nanosecond. Magnetization of the fixed magnetic layer may remain unchanged since an associated current is below its threshold due to geometry or due to an adjacent anti-ferromagnetic layer.

Spin-transfer torque can be used to flip the active elements in magnetic random access memory. Spin-transfer torque memory, or STTM, has the advantages of lower power consumption and better scalability over conventional magnetic random access memory (MRAM) which uses magnetic fields to flip the active elements. However, significant improvements are still needed in the area of STTM device manufacture and usage.

### BRIEF DESCRIPTION OF THE DRAWINGS

FIG. 1 illustrates a cross-sectional view of a material layer stack for a spin transfer torque memory (STTM) device, with an expanded view of three layers of a magnetic tunneling junction (MTJ) of the STTM device, in accordance with an embodiment of the present invention.

FIG. 2A illustrates a cross-sectional view of a conventional thick single metal (Ru) electrode.

FIG. 2B illustrates a cross-sectional view of a Ru/Ta interleaved material stack electrode, in accordance with an embodiment of the present invention.

FIG. 3 is a transmission electron microscope (TEM) image of a MTJ having a topographically rough bottom electrode.

FIG. 4A is an atomic force microscopy (AFM) measurement plot of a conventional thick single metal (Ru) electrode.

FIG. 4B is an AFM measurement plot of a Ru/Ta interleaved material stack electrode, in accordance with an embodiment of the present invention.

FIG. 5A illustrates a plot of energy (E) as a function of density of states (DOS) for a magnetic layer not including a half-metal material, in accordance with one embodiment of the present invention.

FIG. 5B illustrates plots of energy (E) as a function of density of states (DOS) for a fixed magnetic layer including a half-metal material and for a free magnetic layer including a half-metal material, respectively, and a reading operation of an MTJ including the layers, in accordance with another embodiment of the present invention.

FIG. 6 illustrates a schematic of a spin transfer torque memory bit cell which includes a spin transfer torque element, in accordance with an embodiment of the present invention.

FIG. 7 illustrates a block diagram of an electronic system, in accordance with an embodiment of the present invention.

FIG. 8 illustrates a computing device in accordance with one implementation of the invention.

### DESCRIPTION OF THE EMBODIMENTS

Spin transfer torque memory (STTM) devices with topographically smooth electrodes and methods of fabricating STTM devices with topographically smooth electrodes are described. In the following description, numerous specific details are set forth, such as specific magnetic layer integration and material regimes, in order to provide a thorough understanding of embodiments of the present invention. It will be apparent to one skilled in the art that embodiments of the present invention may be practiced without these specific details. In other instances, well-known features, such as integrated circuit design layouts, are not described in detail in order to not unnecessarily obscure embodiments of the present invention. Furthermore, it is to be understood that the various embodiments shown in the Figures are illustrative representations and are not necessarily drawn to scale.

One or more embodiments described herein are directed at spin transfer torque embedded memory. One or more topographically smooth electrodes may be included in such a memory device. By forming a dielectric layer, such as magnesium oxide (MgO) above a topographically smooth electrode, performance of a corresponding magnetic tunnel junction (MTJ) may be improved. For example, conventional MgO roughness resulting from formation above an otherwise topographically rough electrode may lead to high critical switching current density (Jc) in the MTJ and a detrimentally low tunneling magneto-resistance ratio. Much of the roughness may originate from use of a thick bottom electrode, typically made of ruthenium. Ruthenium (Ru) is one of the smoother metals, and reason it is used, but still may be too rough for MgO films which are typically only approximately 1 nanometer thick. The roughness may stem from a columnar grain structure in the electrode.

An advantage of implementation one or more embodiments described herein may include the enablement of a topographically smooth layer or stack of layers onto which a dielectric layer (e.g., MgO) of an MTJ is formed. Since a smoother starting surface is provided, the quality and reproducibility of the dielectric layer may be improved, e.g., since a smoother dielectric layer may thus be fabricated. In an exemplary embodiment, interleaving different materials, such as tantalum (Ta), with the Ru may serves to inhibit or at least mitigate columnar grain structure formation in the Ru. Such columnar grain structure in an otherwise Ru-only electrode leads to the roughness in the Ru-only structure. Ru is typically chosen as a bottom electrode in a stack of materials used to fabricate an MTJ-based device because it is smoother than most metals and is also highly conductive. Nonetheless, embodiments described herein provide further topographical smoothening of an electrode, e.g., by interleaving different materials to keep grain size small and, hence, the roughness very small.

A surface topography of an electrode may be a concern where a relatively thicker electrode is need. For example, in an embodiment, a bottom electrode below an MTJ stack is used for device testing or for high conductivity contact formation. As such, a smooth surface roughness may not necessarily be achievable by merely keeping a thickness of the electrode to a minimum since a thick electrode may be needed.

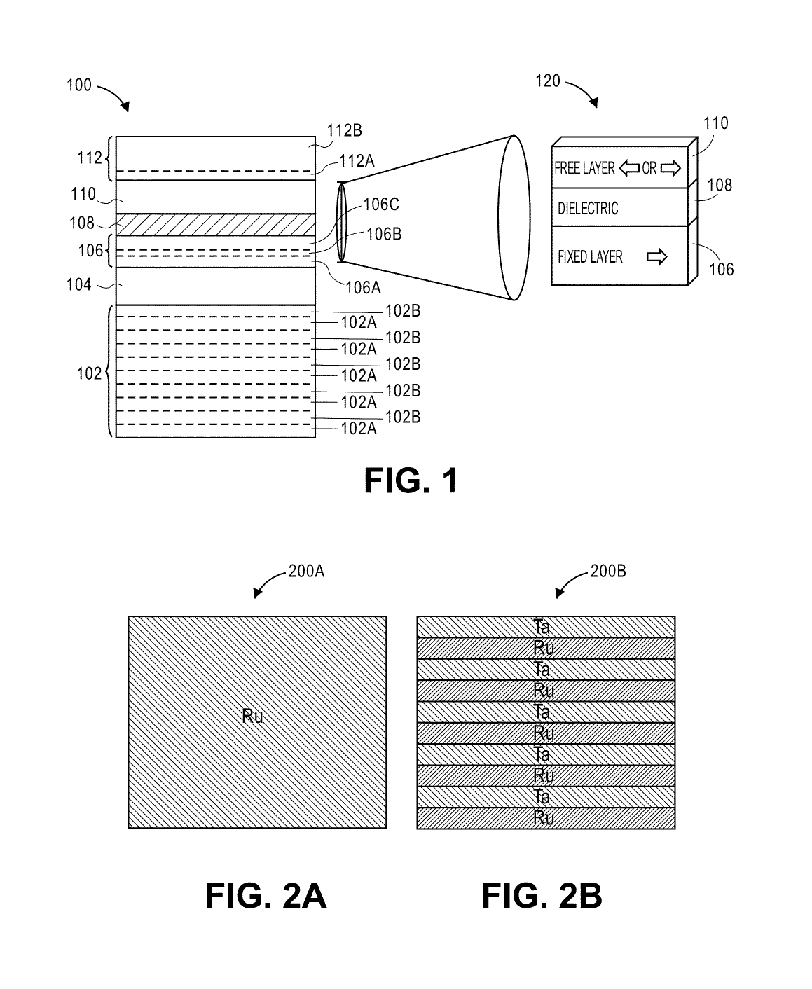

Thus, in an aspect, a topographically smooth electrode may be included in a stack of materials including an MTJ, e.g., for use in a memory device. For example, FIG. 1 illustrates a cross-sectional view of a material layer stack for a STTM device, with an expanded view of three layers of an MTJ of the STTM device, in accordance with an embodiment of the present invention.

Referring to FIG. 1, a material layer stack 100 for a STTM device includes a bottom electrode 102, an anti-ferromagnetic layer 104, a fixed magnetic layer 106, a dielectric layer 108, a free magnetic layer 110, and a top electrode 112. As shown on the right-hand side of FIG. 1, an MTJ portion 120 of the material layer stack 100 includes the fixed magnetic layer 106, the dielectric layer 108, and the free magnetic layer 110.

The bottom electrode 102 may be composed of a material or stack of materials suitable for electrically contacting the fixed magnetic layer side of a STTM device. In an embodiment, the bottom electrode 102 is a topographically smooth electrode. In one such embodiment, the bottom electrode 102 has a thickness suitable for good conductivity but has little to no columnar structure formation that would otherwise lead to a rough top surface. Such a topographically smooth electrode may be referred to as amorphous in structure. In a specific embodiment, the bottom electrode is composed of Ru layers interleaved with Ta layers, as mentioned briefly above.

For example, referring to again to FIG. 1, the bottom electrode 102 is composed of Ru layers 102A interleaved with Ta layers 102B. It is to be understood that the actual arrangement of layers 102A/102B may be opposite to that shown, or may begin and end with 102A, or may begin and end with 102B. Effectively, referring to FIGS. 2A and 2B, in accordance with an embodiment of the present invention, the bottom electrode 102 is not a conventional thick single metal electrode, such as a Ru electrode 200A depicted in FIG. 2A, but is instead a Ru/Ta interleaved materials stack such as stack 200B depicted in FIG. 2B.

In an embodiment, the topographically smooth bottom electrode has a peak-to-peak surface roughness of less than approximately 3 nanometers. In an embodiment, the topographically smooth bottom electrode has a root mean square surface roughness (ZRMS) of less than approximately 3.5 Angstroms. In an embodiment, the topographically smooth bottom electrode is composed of alternating layers of ruthenium (Ru) and tantalum (Ta), each layer having a thickness approximately in the range of 1-5 nanometers, and the topographically smooth bottom electrode has a total thickness of approximately 50 nanometers. In an embodiment, the topographically smooth bottom electrode is amorphous. In an embodiment, the topographically smooth bottom electrode is essentially free from a columnar structure.

In an embodiment, forming the topographically smooth bottom electrode includes forming alternating layers of a first metal and a second, different, metal. In one such embodiment, forming the alternating layers of the first metal and the second metal includes co-sputtering, at the same time from two different targets, tantalum (Ta) and ruthenium (Ru). In such co-sputtering, in one embodiment, the atoms in the film (e.g., Ta and Ru) are intermixed and there is no distinct layering. In another such embodiment, forming the alternating layers of the first metal and the second metal includes co-sputtering, sequentially from two different targets, tantalum (Ta) and ruthenium (Ru).

It is to be understood that other approaches and materials may be used to form a topographically smooth electrode. For example, in an embodiment, alternating metals with conductivity may be used so long as they do not form alloy, which may otherwise lead to surface roughness. The different metals may be co-sputtered or may be intermixed, so long as the final stack provides a good conductivity electrode. In an embodiment, any suitable metal or metals may be used so long as the final electrode is amorphous or is essentially amorphous. The actual thickness of the layers may vary. Zero nanometer layers would be representative of a complete mixing of the two metals to form an alloy of Ru—X, where X can be Ta, Mo, W, Cu. And, even Ru may be replaced with, e.g., copper (Cu) which is also highly conductive. As such, in an embodiment, Cu—X multilayers are used to form an electrode for an MTJ stack. A thickness of each layer may be approximately, at a high end, 5 nanometers to prevent large crystalline grains from forming.

In an embodiment, the anti-ferromagnetic layer 104 is composed of a material suitable to facilitate locking of the spins in an adjacent fixed magnetic layer, such as fixed magnetic layer 106. In one embodiment, the anti-ferromagnetic layer 104 is composed of a material such as, but not limited to, iridium manganese (IrMn) or platinum manganese (PtMn).

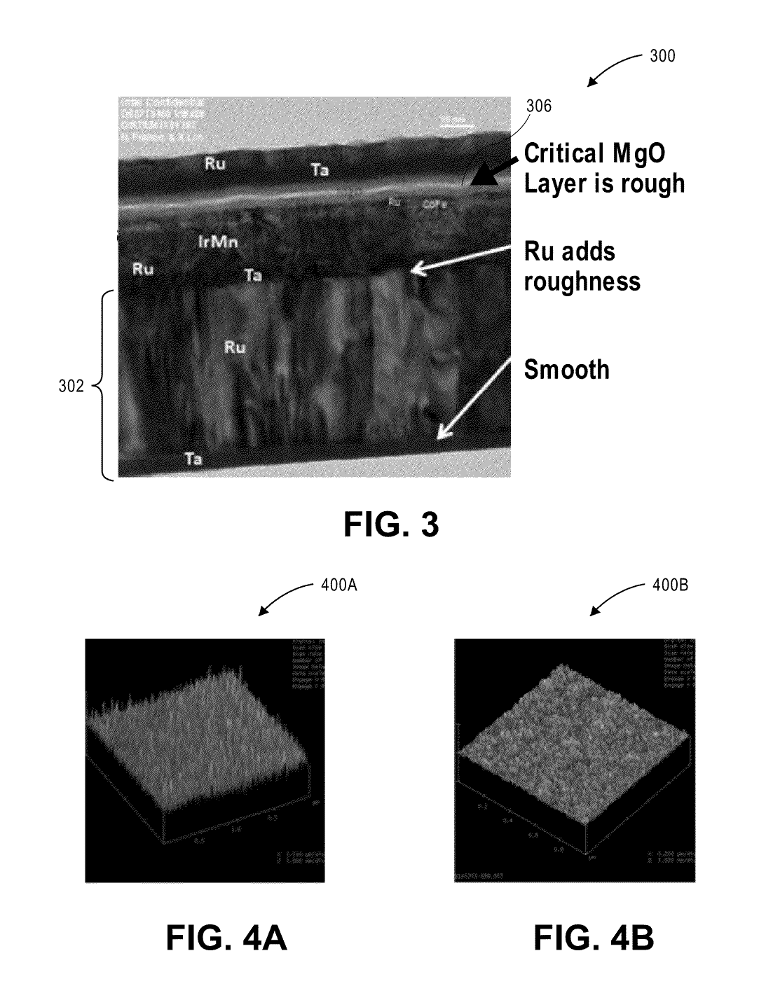

In an embodiment, the fixed magnetic layer 106 is composed of a material or stack of materials suitable for maintaining a fixed majority spin. Thus, the fixed magnetic layer 106 (or reference layer) may be referred to as a ferromagnetic layer. In one embodiment, the fixed magnetic layer 106 is composed of a single layer of cobalt iron boride (CoFeB). However, in another embodiment, the fixed magnetic layer 106 is composed of a cobalt iron boride (CoFeB) layer 106A, ruthenium (Ru) layer 106B, cobalt iron boride (CoFeB) layer 106C stack, as depicted in FIG. 1. In a specific such embodiment, the fixed magnetic layer is in the form of a synthetic antiferromagnet (SAF). From a top down perspective, the stack is a CoFeB/Ru/CoFe stack (e.g., no boron in the bottom layer, but there may be in other embodiments). It is to be understood that Ru thickness is very specific, e.g., 8-9 Angstroms such that the coupling between the CoFeB and the CoFe is anti-ferromagnetic; they point in opposite directions. The direction of the bottom electrode is determined by the direction within the CoFeB layer. In a particular such embodiment, as shown in FIG. 3 below, the material stack includes both SAF and natural AF (IrMn) below it.

In an embodiment, the dielectric layer 108 is composed of a material suitable for allowing current of a majority spin to pass through the layer, while impeding at least to some extent current of a minority spin to pass through the layer. Thus, the dielectric layer 108 (or spin filter layer) may be referred to as a tunneling layer. In one embodiment, the dielectric layer 108 is composed of a material such as, but not limited to, magnesium oxide (MgO) or aluminum oxide (Al₂O₃). In one embodiment, the dielectric layer 108 has a thickness of approximately 1 nanometer.

In an embodiment, the dielectric layer 108 is a topographically smooth dielectric layer. In one such embodiment, the dielectric layer 108 is topographically smooth since it is fabricated on a material stack including a topographically smooth bottom electrode 102, as described above. To better illustrate the concepts involved, FIG. 3 is a transmission electron microscope (TEM) image 300 of a MTJ having a topographically rough bottom electrode. Referring to FIG. 3, the bottom electrode 302 includes a thin smooth layer of tantalum (Ta), a thick layer of ruthenium (Ru), and a second layer of Ta. However, the Ru portion is sufficiently thick for columnar growth to occur in the Ru layer. As such, the top surface of the Ru layer is topographically rough, and layers formed thereon or there above are also topographically rough. For example, a MgO dielectric layer 306 formed above the electrode 306 is topographically rough, as can be viewed in image 300. Since the roughness of the Ru layer propagates through to the MgO layer, performance quality of the MgO layer is compromised. Accordingly, as described above, in an embodiment, the MgO layer is fabricated herein to be smooth since it is formed above a smooth bottom electrode. In one such embodiment, magneto-resistance changes for devices including a smooth MgO layer are increased over conventional rough electrode devices, improving the memory effect of the devices. Furthermore, in an embodiment, the current needed to switch such devices is decreased relative to the higher current needed for a rougher MgO material. It is to be noted that FIG. 3 also includes an antiferromagnetic layer (IrMn) and corresponding seed layer (top Ru) for that layer.

In order to quantify a topographically rough versus topographically smooth electrode, FIG. 4A is an atomic force microscopy (AFM) measurement plot 400A of a conventional thick single metal (Ru) electrode, while FIG. 4B is an AFM measurement plot 400B of a Ru/Ta interleaved material stack electrode, in accordance with an embodiment of the present invention. Referring to plot 400A, a single Ru layer having a thickness of approximately 50 nanometers has a peak-to-peak surface roughness of approximately 5.8 nanometers and a root mean square surface roughness (Z_{RMS}) of approximately 5.4 Angstroms. Referring to plot 400B, an alternating stack of Ru and Ta layers (each layer approximately 2 nanometers thick and a total stack thickness of approximately 24 nanometers) has a peak-to-peak surface roughness of approximately 1.9 nanometers and a root mean square surface roughness (Z_{RMS}) of approximately 2.2 Angstroms. In an embodiment, the former structure is considered to be a topographically rough electrode, while the latter structure is considered to be a topographically smooth electrode. In either case, in accordance with an embodiment of the present invention, the surface topography (rough or smooth) is propagated through to an overlying dielectric layer, such as a MgO dielectric layer of a MTJ.

In an embodiment, the free magnetic layer 110 is composed of a material suitable for transitioning between a majority spin and a minority spin, depending on the application. Thus, the free magnetic layer 110 (or memory layer) may be referred to as a ferromagnetic memory layer. In one embodiment, the free magnetic layer 110 is composed of a layer of cobalt iron (CoFe) or cobalt iron boride (CoFeB).

In an embodiment, the top electrode 112 is composed of a material or stack of materials suitable for electrically contacting the free magnetic layer side of a STTM device. In one embodiment, the top electrode 112 is composed of a ruthenium (Ru) layer 112A, contact metal layer 112B stack, as depicted in FIG. 1. The ruthenium layer 112A may be included to prevent oxygen migration into the free magnetic layer 110. The metal contact layer may provide a low resistance path for conduction of current, and may be composed of material such as, but not limited to, copper, aluminum, nickel, and cobalt. In another embodiment, the top electrode 112 may be composed of essentially the same material stack as bottom electrode 102, e.g., as an interleaved and amorphous, thick, conductive stack. Thus, both electrodes in stack 100 may be topographically smooth electrodes. However, it is to be understood that such topographical considerations may only be necessary for the underlying electrode, which may dictate the smoothness of the dielectric layer 108.

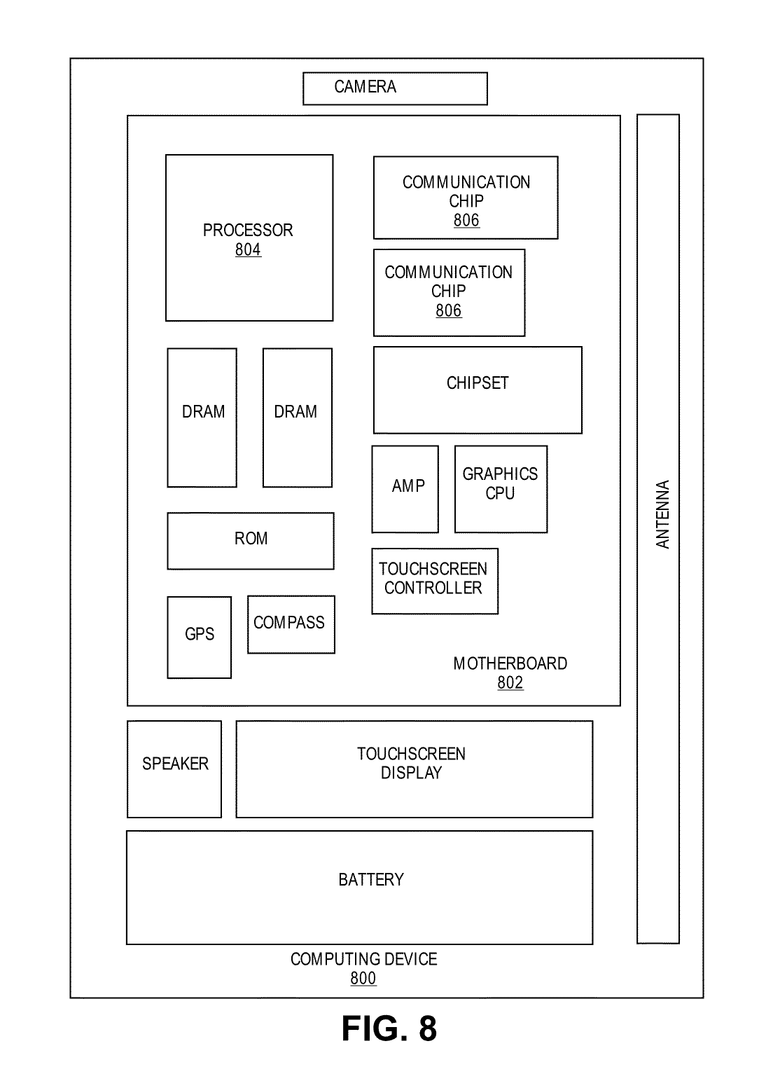

In an embodiment, as described in additional detail later in association with FIG. 8, a non-volatile memory device includes a first electrode and a fixed magnetic layer disposed above the first electrode. A free magnetic layer is disposed above the fixed magnetic layer, and a second electrode is disposed above the free magnetic layer. A dielectric layer is disposed between the free magnetic layer and the fixed magnetic layer. One or both of the first and second electrodes is a topographically smooth electrode. The non-volatile memory device also includes a transistor electrically connected to the free magnetic layer electrode, a source line, and a word line. In one embodiment, the non-volatile memory device further includes an anti-ferromagnetic layer disposed between the fixed magnetic layer and the first electrode.

In certain aspects and at least some embodiments of the present invention, certain terms hold certain definable meanings. For example, a “free” magnetic layer is a magnetic layer storing a computational variable. A “fixed” magnetic layer is a magnetic layer with permanent magnetization. A tunneling barrier, such as a tunneling dielectric or tunneling oxide, is one located between free and fixed magnetic layers. A fixed magnetic layer may be patterned to create inputs and outputs to an associated circuit. Magnetization may be written by spin transfer torque effect while passing a current through the input electrodes. Magnetization may be read via the tunneling magneto-resistance effect while applying voltage to the output electrodes. In an embodiment, the role of the dielectric layer 108 is to cause a large magneto-resistance ratio. The magneto-resistance is the ratio of the difference between resistances when the two ferromagnetic layers have anti-parallel and parallel magnetization and the resistance of the state with the parallel magnetization.

Referring again to the right-hand side of FIG. 1, the portion 120 of the spin transfer torque element 100 including the free magnetic layer 110, the tunneling barrier layer 108, and the fixed magnetic layer 106 is known as a magnetic tunneling junction. The free magnetic layer 110 and the fixed magnetic layer 106 may be ferromagnetic layers which are able to hold a magnetic field or polarization. However, the fixed magnetic layer 106 is configured to hold the majority spin state (e.g., depicted as spin to the right for planar spin state or spin up for vertical spin state). The tunneling barrier layer 108, which separates the free magnetic layer 110 and the fixed magnetic layer 106, may have a thickness, e.g. a distance between the free magnetic layer 110 and the fixed magnetic layer 106 of about 1 nanometer or less, such that electrons can tunnel there through, if a bias voltage is applied between the free magnetic layer electrode 112 and the fixed magnetic layer electrode 102.

In an embodiment, the MTJ 120 functions essentially as a resistor, where the resistance of an electrical path through the MTJ 120 may exist in two resistive states, either “high” or “low,” depending on the direction or orientation of magnetization in the free magnetic layer 110 and in the fixed magnetic layer 106. Referring to FIG. 1, in the case that the spin direction is to the left (minority) in the free magnetic layer 110, a high resistive state exists, wherein direction of magnetization in the free magnetic layer 110 and the fixed magnetic layer 106 are substantially opposed or anti-parallel with one another. This is illustrated with arrows in the free magnetic layer 110 pointing left and in the fixed magnetic layer 106 pointing right. Referring again to FIG. 1, in the case that the spin direction is to the right (majority) in the free magnetic layer 110, a low resistive state exists, wherein the direction of magnetization in the free magnetic layer 110 and the fixed magnetic layer 106 is substantially aligned or parallel with one another. This is illustrated with arrows in the free magnetic layer 110 pointing right and in the fixed magnetic layer 106 pointing right. It is understood that the terms “low” and “high” with regard to the resistive state of the MTJ 120 are relative to one another. In other words, the high resistive state is merely a detectably higher resistance than the low resistive state, and vice versa. Thus, with a detectable difference in resistance, the low and high resistive states can represent different bits of information (i.e. a “0” or a “1”).

The direction of magnetization in the free magnetic layer 110 may be switched through a process call spin transfer torque (“STT”) using a spin-polarized current. An electrical current is generally non-polarized (e.g. consisting of about 50% spin-up and about 50% spin-down electrons). A spin polarized current is one with a greater number of electrons of either spin-up or spin-down, which may be generated by passing a current through the fixed magnetic layer 106. The electrons of the spin polarized current from the fixed magnetic layer 106 tunnel through the tunneling barrier or dielectric layer 108 and transfers its spin angular momentum to the free magnetic layer 110, wherein the free magnetic layer 110 will orient its magnetic direction from anti-parallel to that of the fixed magnetic layer 106 or parallel. The free magnetic layer 110 may be returned to its original orientation by reversing the current.

Thus, the MTJ 120 may store a single bit of information (“0” or “1”) by its state of magnetization. The information stored in the MTJ 120 is sensed by driving a current through the MTJ 120. The free magnetic layer 110 does not require power to retain its magnetic orientations. As such, the state of the MTJ 120 is preserved when power to the device is removed. Therefore, a spin transfer torque memory bit cell composed of the stack 100 of FIG. 1 is, in an embodiment, non-volatile.

Although the method of fabricating the stack of layers 100 for, e.g., a spin transfer torque memory bit cell has not been described complete detail herein, it is understood that the steps for fabrication may include standard microelectronic fabrication processes such as lithography, etch, thin films deposition, planarization (such as chemical mechanical polishing (CMP)), diffusion, metrology, the use of sacrificial layers, the use of etch stop layers, the use of planarization stop layers, and/or any other associated action with microelectronic component fabrication.

In accordance with another embodiment of the present invention, one of the fixed magnetic layer 106, the free magnetic layer 110, or both, includes a half-metal material layer. In a first example, in one embodiment, a half-metal material layer is included at the fixed magnetic layer 106 and dielectric layer 108 interface. In a specific such embodiment, the fixed magnetic layer 106 is a single layer composed of the half-metal material. However, in another specific embodiment, only a portion of the fixed magnetic layer 106 is composed of the half-metal material, e.g., in place of the cobalt iron (CoFe) or cobalt iron boride (CoFeB) layer 106C, described above. In a second example, in another embodiment, a half-metal material layer is included at the free magnetic layer 110 and dielectric layer 108 interface. In a specific such embodiment, the free magnetic layer 110 is a single layer composed of the half-metal material. However, in another specific embodiment, only a portion of the free magnetic layer 110 is composed of the half-metal material, e.g., as a sub-layer at the interface with the dielectric layer 108. In a third example, in yet another embodiment, a first half-metal material layer is included at the fixed magnetic layer 106 and dielectric layer 108 interface and a second half-metal material layer is included at the free magnetic layer 110 and dielectric layer 108 interface. In an embodiment, half-metals (e.g. Heusler alloys) are included to increase the difference between anti-parallel resistance (RAP) and parallel resistance (RP) (i.e. AR) in magnetic tunneling junction (MTJ) devices.

In an embodiment, the half-metal material layers described above are referred to as a Heusler alloy, which is a ferromagnetic metal alloy based on a Heusler phase. Heusler phases may be intermetallics with particular composition and face-centered cubic crystal structure. The materials are ferromagnetic, even though the constituting elements are not, as a result of the double-exchange mechanism between neighboring magnetic ions. The materials usually include manganese ions, which sit at the body centers of the cubic structure and carry most of the magnetic moment of the alloy. In a specific embodiment, the half-metal material layer included in either the fixed magnetic layer 106, the free magnetic layer 110, or both, are material layers such as, but not limited to, Cu₂MnAl, Cu₂MnIn, Cu₂MnSn, Ni₂MnAl, Ni₂MnIn, Ni₂MnSn, Ni₂MnSb, Ni₂MnGa, Co₂MnAl, Co₂MnSi, Co₂MnGa, Co₂MnGe, Pd₂MnAl, Pd₂MnIn, Pd₂MnSn, Pd₂MnSb, Co₂FeSi, Fe₃Si, Fe₂Val, Mn₂VGa, or Co₂FeGe. One or both of the corresponding electrodes includes a half-metal material at an interface with the dielectric layer. In one embodiment, only the fixed magnetic layer includes a half-metal material at the interface with the dielectric layer. In a specific such embodiment, the fixed magnetic layer further includes a ferroelectric material adjacent the half-metal material, distal from the interface of the fixed magnetic layer with the dielectric layer. In another specific such embodiment, the free magnetic layer includes a ferroelectric material. In a particular such embodiment, the free magnetic layer further includes a half-metal material adjacent to the ferroelectric material, distal from the interface of the free magnetic layer with the dielectric layer. In an embodiment, the magnetic tunneling junction further includes an anti-ferromagnetic layer adjacent to the fixed magnetic layer, distal from the interface of the fixed magnetic layer with the dielectric layer.

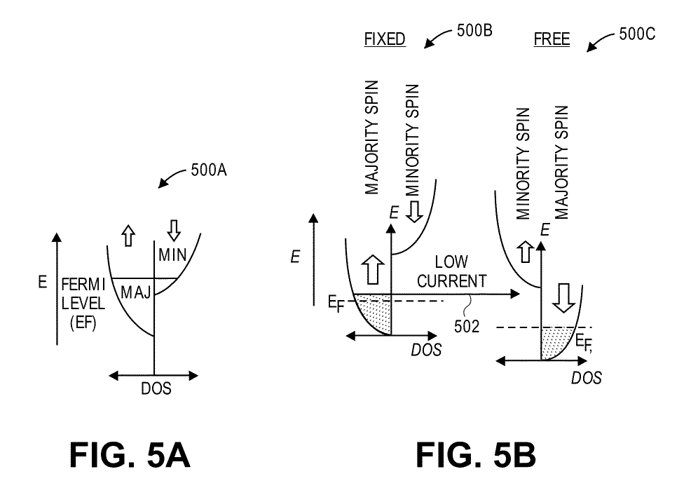

Thus, in another aspect, a reading or writing operation may be performed on a memory element including an MTJ with a half-metal layer. FIG. 5A illustrates a plot 500A of energy (E) as a function of density of states (DOS) for a magnetic layer not including a half-metal material, in accordance with one embodiment of the present invention. FIG. 5B illustrates plots 500B and 500C of energy (E) as a function of density of states (DOS) for a fixed magnetic layer including a half-metal material and for a free magnetic layer including a half-metal material, respectively, and a reading operation of an MTJ including the layers, in accordance with another embodiment of the present invention.

Referring to FIG. 5A, at the Fermi energy level (EF), a magnetic layer not including a half-metal material includes both majority spin (spin up) and minority spin (spin down) states. By contrast, referring to FIG. 5B, in both the fixed magnetic material including a half-metal material and the free magnetic material including a half-metal material, only (or at least essentially all) of the spin states are majority (spin up) spin states at the Fermi energy level.

In MTJs, high and low resistance states occur when spins in free and fixed magnetic layers are anti-parallel and parallel, respectively. High resistance can be referred to as RAP, while low resistance can be referred to as RP. Referring again to FIG. 5B, regarding reading a MTJ where both the fixed magnetic material includes a half-metal material and the free magnetic material includes a half-metal material, half metals have a split in conduction bands between up and down spins. Hence, there are electrons with only one spin orientation at the Fermi level. RAP is increased since there are, ideally, no available states to tunnel into. Increased RAP results in a larger resistance difference (ΔR) between anti-parallel and parallel states (e.g., since ΔR=RAP−RP). This increased ΔR can enhance reading 502 of an MTJ.

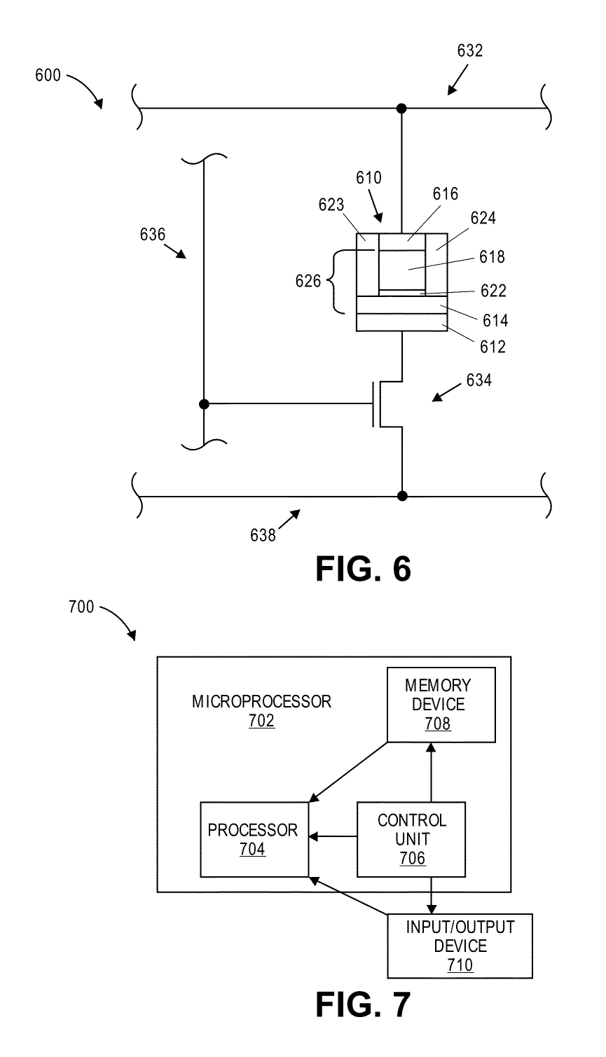

Referring again to the description associated with FIGS. 1, 2A, 2B, 3, 4A and 4B, a stack of layers including magnetic material layers and one or more topographically smooth electrodes, e.g., which are used in a magnetic tunneling junction, may be used to fabricate as memory bit cell. For example, FIG. 6 illustrates a schematic of a spin transfer torque memory bit cell 600 which includes a spin transfer torque element 610, in accordance with an embodiment of the present invention.

Referring to FIG. 6, the spin transfer torque element 610 may include a free magnetic layer electrode 612 with a free magnetic layer 614 adjacent the free magnetic layer electrode 612, a fixed magnetic layer electrode 616 adjacent a fixed magnetic layer 618, and a tunneling barrier or dielectric layer 622 disposed between the free magnetic layer 614 and the fixed magnetic layer 618. In an embodiment, one or both of the free magnetic layer electrode 612 and the fixed magnetic layer electrode 616 is a topographically smooth electrode.

A first dielectric element 623 and a second dielectric element 624 may be formed adjacent the fixed magnetic layer electrode 616, the fixed magnetic layer 618, and the tunneling barrier or dielectric layer 622. The fixed magnetic layer electrode 616 may be electrically connected to a bit line 632. The free magnetic layer electrode 612 may be coupled with a transistor 634. The transistor 634 may be coupled with a word line 636 and a source line 638 in a manner that will be understood to those skilled in the art. The spin transfer torque memory bit cell 600 may further include additional read and write circuitry (not shown), a sense amplifier (not shown), a bit line reference (not shown), and the like, as will be understood by those skilled in the art, for the operation of the spin transfer torque memory bit cell 600. It is to be understood that a plurality of the spin transfer torque memory bit cells 600 may be operably connected to one another to form a memory array (not shown), wherein the memory array can be incorporated into a non-volatile memory device. It is to be understood that the transistor 634 may be connected to the fixed magnetic layer electrode 616 or the free magnetic layer electrode 612, although only the latter is shown.

FIG. 7 illustrates a block diagram of an electronic system 700, in accordance with an embodiment of the present invention. The electronic system 700 can correspond to, for example, a portable system, a computer system, a process control system, or any other system that utilizes a processor and an associated memory. The electronic system 700 may include a microprocessor 702 (having a processor 704 and control unit 706), a memory device 708, and an input/output device 710 (it is to be understood that the electronic system 700 may have a plurality of processors, control units, memory device units and/or input/output devices in various embodiments). In one embodiment, the electronic system 700 has a set of instructions that define operations which are to be performed on data by the processor 704, as well as, other transactions between the processor 704, the memory device 708, and the input/output device 710. The control unit 706 coordinates the operations of the processor 704, the memory device 708 and the input/output device 710 by cycling through a set of operations that cause instructions to be retrieved from the memory device 708 and executed. The memory device 708 can include a spin transfer torque element as described in the present description. In an embodiment, the memory device 708 is embedded in the microprocessor 702, as depicted in FIG. 7.

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor includes one or more devices, such as spin transfer torque memory built in accordance with implementations of the invention. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip includes one or more devices, such as spin transfer torque memory built in accordance with implementations of the invention.

In further implementations, another component housed within the computing device 800 may contain an integrated circuit die that includes one or more devices, such as spin transfer torque memory built in accordance with implementations of the invention.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

Accordingly, one or more embodiments of the present invention relate generally to the fabrication of microelectronic memory. The microelectronic memory may be non-volatile, wherein the memory can retain stored information even when not powered. One or more, embodiments of the present invention relate to the fabrication of a spin transfer torque memory element for non-volatile microelectronic memory devices. Such an element may be used in an embedded non-volatile memory, either for its non-volatility, or as a replacement for embedded dynamic random access memory (eDRAM). For example, such an element may be used for 1T-1X memory (X=capacitor or resistor) at competitive cell sizes within a given technology node.

Thus, embodiments of the present invention include spin transfer torque memory (STTM) devices with topographically smooth electrodes and methods of fabricating STTM devices with topographically smooth electrodes.

In an embodiment, a material layer stack for a magnetic tunneling junction includes a topographically smooth bottom electrode, a topographically smooth dielectric layer disposed above the bottom electrode, and a free magnetic layer disposed above the topographically smooth dielectric layer.

In one embodiment, the topographically smooth bottom electrode has a peak-to-peak surface roughness of less than approximately 3 nanometers.

In one embodiment, the topographically smooth bottom electrode has a root mean square surface roughness (ZRMS) of less than approximately 3.5 Angstroms.

In one embodiment, a surface roughness of the topographically smooth dielectric layer is approximately the same as a surface roughness of the topographically smooth bottom electrode.

In one embodiment, the topographically smooth bottom electrode is composed of alternating layers of ruthenium (Ru) and tantalum (Ta), each layer having a thickness approximately in the range of 1-5 nanometers, and the topographically smooth bottom electrode has a total thickness of approximately 50 nanometers.

In one embodiment, the topographically smooth bottom electrode is amorphous.

In one embodiment, the topographically smooth bottom electrode is essentially fee from a columnar structure.

In one embodiment, the material layer stack further includes an anti-ferromagnetic layer disposed on the topographically smooth bottom electrode, below the topographically smooth dielectric layer.

In one embodiment, the material layer stack further includes a fixed magnetic layer disposed on the anti-ferromagnetic layer, the topographically smooth dielectric layer is disposed on the fixed magnetic layer, and the free magnetic layer is disposed on the topographically smooth dielectric layer.

In one embodiment, the material layer stack further includes a top electrode disposed above the free magnetic layer.

In one embodiment, one or both of the free magnetic layer and the fixed magnetic layer includes a half-metal material at an interface with the topographically smooth dielectric layer.

In one embodiment, the half-metal material is a ferromagnetic metal alloy based on a Heusler phase.

In an embodiment, a non-volatile memory device includes a topographically smooth bottom electrode. An anti-ferromagnetic layer is disposed on the topographically smooth bottom electrode. A fixed magnetic layer is disposed on the anti-ferromagnetic layer. A dielectric layer is disposed on the fixed magnetic layer. A free magnetic layer is disposed on the dielectric layer. A top electrode is disposed on the free magnetic layer. A transistor is electrically connected to the top or the bottom electrode, a source line, and a word line.

In one embodiment, the topographically smooth bottom electrode has a peak-to-peak surface roughness of less than approximately 3 nanometers.

In one embodiment, the topographically smooth bottom electrode has a root mean square surface roughness (ZRMS) of less than approximately 3.5 Angstroms.

In one embodiment, the dielectric layer is a topographically smooth dielectric layer having a surface roughness approximately the same as a surface roughness of the topographically smooth bottom electrode.

In one embodiment, the topographically smooth bottom electrode is composed of alternating layers of ruthenium (Ru) and tantalum (Ta), each layer having a thickness approximately in the range of 1-5 nanometers, and the topographically smooth bottom electrode has a total thickness of approximately 50 nanometers.

In one embodiment, the topographically smooth bottom electrode is amorphous.

In one embodiment, the topographically smooth bottom electrode is essentially fee from a columnar structure.

In one embodiment, one or both of the free magnetic layer and the fixed magnetic layer includes a half-metal material at an interface with the dielectric layer.

In one embodiment, the half-metal material is a ferromagnetic metal alloy based on a Heusler phase.

In one embodiment, the transistor is electrically connected to the topographically smooth bottom electrode, the source line, and the word line.

In one embodiment, the transistor is electrically connected to the top electrode, the source line, and the word line.

In one embodiment, the free magnetic layer is composed of a ferroelectric material.

In an embodiment, a method of fabricating a material layer stack for a magnetic tunneling junction includes forming a topographically smooth bottom electrode above a substrate. A topographically smooth dielectric layer is formed above the bottom electrode. A free magnetic layer is formed above the topographically smooth dielectric layer.

In one embodiment, forming the topographically smooth bottom electrode includes forming alternating layers of a first metal and a second, different, metal.

In one embodiment, forming the alternating layers of the first metal and the second metal includes co-sputtering, at the same time from two different targets, tantalum (Ta) and ruthenium (Ru).

In one embodiment, forming the alternating layers of the first metal and the second metal includes co-sputtering, sequentially from two different targets, tantalum (Ta) and ruthenium (Ru).

In one embodiment, forming the topographically smooth bottom electrode includes forming an electrode having a peak-to-peak surface roughness of less than approximately 3 nanometers.

In one embodiment, forming the topographically smooth bottom electrode includes forming an electrode having a root mean square surface roughness (ZRMS) of less than approximately 3.5 Angstroms.

1. A material layer stack for a magnetic tunneling junction, the material layer stack comprising:
a topographically smooth bottom electrode, wherein the topographically smooth bottom electrode is essentially free from a columnar structure;
a topographically smooth dielectric layer disposed above the bottom electrode; and
a free magnetic layer disposed above the topographically smooth dielectric layer.

2. The material layer stack of claim 1, wherein the topographically smooth bottom electrode has a peak-to-peak surface roughness of less than approximately 3 nanometers.

3. The material layer stack of claim 1, wherein the topographically smooth bottom electrode has a root mean square surface roughness (ZRMS) of less than approximately 3.5 Angstroms.

4. The material layer stack of claim 1, wherein a surface roughness of the topographically smooth dielectric layer is approximately the same as a surface roughness of the topographically smooth bottom electrode.

5. The material layer stack of claim 1, wherein the topographically smooth bottom electrode comprises alternating layers of ruthenium (Ru) and tantalum (Ta).

6. The material layer stack of claim 5, wherein each layer has a thickness approximately in the range of 1-5 nanometers, and wherein the topographically smooth bottom electrode has a total thickness of approximately 50 nanometers.

7. The material layer stack of claim 1, wherein the topographically smooth bottom electrode comprises an intermixture of ruthenium (Ru) and tantalum (Ta).

8. The material layer stack of claim 1, wherein the topographically smooth bottom electrode is amorphous.

9. (canceled)

10. The material layer stack of claim 1, further comprising:
an anti-ferromagnetic layer disposed on the topographically smooth bottom electrode, below the topographically smooth dielectric layer.

11. The material layer stack of claim 10, further comprising:
a fixed magnetic layer disposed on the anti-ferromagnetic layer, wherein the topographically smooth dielectric layer is disposed on the fixed magnetic layer, and wherein the free magnetic layer is disposed on the topographically smooth dielectric layer.

12. The material layer stack of claim 11, further comprising:
a top electrode disposed above the free magnetic layer.

13. The material layer stack of claim 11, wherein one or both of the free magnetic layer and the fixed magnetic layer comprises a half-metal material at an interface with the topographically smooth dielectric layer.

14. The material layer stack of claim 13, wherein the half-metal material is a ferromagnetic metal alloy based on a Heusler phase.

15. A non-volatile memory device, comprising:
a topographically smooth bottom electrode, wherein the topographically smooth bottom electrode is essentially fee from a columnar structure;
an anti-ferromagnetic layer disposed on the topographically smooth bottom electrode;
a fixed magnetic layer disposed on the anti-ferromagnetic layer;
a dielectric layer disposed on the fixed magnetic layer;
a free magnetic layer disposed on the dielectric layer;
a top electrode disposed on the free magnetic layer; and
a transistor electrically connected to the top or the bottom electrode, a source line, and a word line.

16. The non-volatile memory device of claim 15, wherein the topographically smooth bottom electrode has a peak-to-peak surface roughness of less than approximately 3 nanometers.

17. The non-volatile memory device of claim 15, wherein the topographically smooth bottom electrode has a root mean square surface roughness (ZRMS) of less than approximately 3.5 Angstroms.

18. The non-volatile memory device of claim 15, wherein the dielectric layer is a topographically smooth dielectric layer having a surface roughness approximately the same as a surface roughness of the topographically smooth bottom electrode.

19. The non-volatile memory device of claim 15, wherein the topographically smooth bottom electrode comprises alternating layers of ruthenium (Ru) and tantalum (Ta).

20. The non-volatile memory device of claim 19, wherein each layer has a thickness approximately in the range of 1-5 nanometers, and wherein the topographically smooth bottom electrode has a total thickness of approximately 50 nanometers.

21. The non-volatile memory device of claim 15, wherein the topographically smooth bottom electrode comprises an intermixture of ruthenium (Ru) and tantalum (Ta).

22. The non-volatile memory device of claim 15, wherein the topographically smooth bottom electrode is amorphous.

23. (canceled)

24. The non-volatile memory device of claim 15, wherein one or both of the free magnetic layer and the fixed magnetic layer comprises a half-metal material at an interface with the dielectric layer.

25. The non-volatile memory device of claim 24, wherein the half-metal material is a ferromagnetic metal alloy based on a Heusler phase.

26. The non-volatile memory device of claim 15, wherein the transistor is electrically connected to the topographically smooth bottom electrode, the source line, and the word line.

27. The non-volatile memory device of claim 15, wherein the transistor is electrically connected to the top electrode, the source line, and the word line.

28. (canceled)

29. A method of fabricating a material layer stack for a magnetic tunneling junction, the method comprising:
forming a topographically smooth bottom electrode above a substrate, wherein the topographically smooth bottom electrode is essentially fee from a columnar structure;
forming a topographically smooth dielectric layer above the bottom electrode; and
forming a free magnetic layer above the topographically smooth dielectric layer.

30. The method of claim 29, wherein forming the topographically smooth bottom electrode comprises forming alternating layers of a first metal and a second, different, metal.

31. The method of claim 30, wherein forming the alternating layers of the first metal and the second metal comprises co-sputtering, at the same time from two different targets, tantalum (Ta) and ruthenium (Ru).

32. The method of claim 30, wherein forming the alternating layers of the first metal and the second metal comprises co-sputtering, sequentially from two different targets, tantalum (Ta) and ruthenium (Ru).

33. The method of claim 29, wherein forming the topographically smooth bottom electrode comprises forming an electrode having a peak-to-peak surface roughness of less than approximately 3 nanometers.

34. The method of claim 29, wherein forming the topographically smooth bottom electrode comprises forming an electrode having a root mean square surface roughness (ZRMS) of less than approximately 3.5 Angstroms.
